(19) United States
(12) Patent Application Publication
(10) Pub. No.: US 2009/0140749 A1
(43) Pub. Date: Jun. 4, 2009

(54) Device for Measuring a Load Current

(75) Inventor: Jurgen Spah, Uberlingen (DE)

Correspondence Address: LERNER GREENBERG STEMER LLP, P O BOX 2480, HOLLYWOOD, FL, 33022-2480, US

(73) Assignee: DIEHL AEROSPACE GMBH, Uberlingen (DE)

(21) Appl. No.: 12/328,111

(22) Filed: Dec. 4, 2008

(30) Foreign Application Priority Data
Dec. 4, 2007 (DE) 10 2007 058 314.3

(51) Int. Cl. G01R 27/00

(52) U.S. Cl. 324/600

(57) ABSTRACT

A device for measuring a load current in a load circuit that has a switch that switches the load current. The switch has a control variable as a first switch variable and an output variable, which is dependent on the control variable, as a second switch variable. A setting unit keeps one of the switch variables constant at a predetermined value, and an evaluation unit determines the load current from the other switch variable. It is thus possible to dispense with an additional measuring element for measuring the load current, thus keeping the power loss low.

### CROSS-REFERENCE TO RELATED APPLICATION

This application claims the priority, under 35 U.S.C. §119, of German application DE 10 2007 058 314.3, filed Dec. 7, 2007; the prior application is herewith incorporated by reference in its entirety.

### BACKGROUND OF THE INVENTION

1. Field of the Invention

The invention relates to a device for measuring a load current in a load circuit having a switch for switching the load current.

In an electrical load circuit having a voltage source and a load connected thereto, such as a motor or another load, there is a need for a switch in order to switch the load or load circuit on and off. If a discrete switch is used and the load current in the load circuit is intended to be measured, a measuring element is integrated in the load circuit, the measuring resistance of the element giving rise to a small voltage drop which can be used to determine the load current.

### SUMMARY OF THE INVENTION

It is accordingly an object of the invention to provide a device for measuring a load current which overcomes the above-mentioned disadvantages of the heretofore-known devices and methods of this general type and which provides for a device that is particularly suitable for measuring a load current in a load circuit in the case of a low voltage across the load.

With the foregoing and other objects in view there is provided, in accordance with the invention, a device for measuring a load current in a load circuit, comprising:

a switch for switching the load current, said switch having a control variable forming a first switch variable and an output variable forming a second switch variable, the output variable being dependent on the control variable;

setting means connected to said switch and configured to keep one of the switch variables constant at a predetermined value; and

an evaluation unit configured to determine the load current from the other switch variable.

In other words, the objects of the invention are achieved in that the switch has a control variable as a first switch variable and an output variable, which is dependent on the control variable, as a second switch variable, and in that the novel device includes a setting means for keeping one of the switch variables constant at a predetermined value, and an evaluation unit for determining the load current from the other switch variable. This apparatus can be used to determine the load current by means of a measurement at the switch, without the need for a separate measuring element.

In this case, the invention is based on the consideration that, in the case of a load which is designed for a low voltage, only a low voltage is also dropped across a measuring resistor. If the measurement requires a predefined higher voltage drop, a measuring resistor with a corresponding high resistance must be provided. As a result, the measuring resistor produces a disadvantageous power loss. Measuring the load current at the switch makes it possible to dispense with the measuring element and the measuring resistance associated with the latter, and to keep the power loss of the load circuit low.

The switch may be arranged in the load circuit and is advantageously a discrete switch with an on position or an on state and an off position or an off state. In its on position or on state, it expediently has a lower electrical resistance than a further element operated in the load circuit, with the result that the load current in the load circuit is determined by the further element and not by the switch. The element, for example the load, thus has a resistance which is greater than the resistance of the switch.

Any switch with a control variable and an output variable dependent on the latter is suitable as the switch, the output variable—irrespective of the discreteness of the switch—expediently being able to be set in at least a plurality of stages and having, in particular, an—at least substantially—continuous characteristic curve between the control variable and the output variable. In this case, the load circuit is expediently designed in such a manner that the operating point on the characteristic curve can be changed without changing from the on position or on state to the off position or off state. In particular, the operating point can be changed in the main part of the operating range of the characteristic curve without changing from “on” to “off” or vice versa in the process.

A transistor, in particular an FET (field effect transistor), of which a MOSFET (Metal Oxide Semiconductor FET), in particular a normally off n-channel MOSFET, is used in a particularly advantageous manner, is particularly suitable for a switch with a characteristic curve.

The load current can be determined from one switch variable or the other. The load current can thus be determined in a particularly simple manner from the switch voltage, from the voltage between the drain and the source or the drain voltage in the case of an FET. In this case, the control variable, for example the voltage between the gate and the source or the gate voltage, is kept constant. The load current can be determined from the known relationship between the control variable, the switch voltage and the load current.

However, it is particularly advantageous if the evaluation unit is intended to determine the load current from the control variable, from the gate voltage in the case of an FET. In this case, the output variable may be a voltage across the switch, and the setting means is intended to keep the voltage across the switch constant. When an FET is used as the switch, the drain voltage may thus be kept constant and the load current is determined from the known relationship between the control variable, the switch voltage and the load current.

The switch variable, in particular the switch voltage, can be kept constant in a particularly simple manner if the setting means has a control loop for keeping the switch variable constant. In this case, the switch variable which is to be kept constant can be used as a control input, the control output determining the other switch variable. In particular, the control output is the other switch variable. The value of the switch variable, which is to be set to be constant, can be set using a reference variable, for example a reference voltage.

In one advantageous embodiment of the invention, the evaluation unit is intended to determine an activity state of the switch from one of the switch variables. The switch variable which is kept constant can thus then be interrogated in a discrete manner or can be permanently monitored in order to determine whether it adheres to the constant value which has been set or does not permanently adhere to the value despite a mechanism for keeping it constant. This may indicate an overload state of the switch and may be used as a criterion for disconnecting the load current. As a result, an overload state would be detected as the activity state. A status of the switch, for example whether the switch is “on” or “off”, can be detected as a further activity state, for example by interrogating or monitoring in order to determine whether the switch variable has the constant value or is at zero, for example. Instead of or in addition to the switch variable which is kept constant, the output variable can be interrogated or monitored and the activity state can be determined from its value. If the output variable is at zero or in saturation, for example, it is possible to infer that the current has been disconnected or that there is an overload.

The evaluation unit is advantageously intended to monitor the switch variable which is kept constant and to emit a signal in the case of a predetermined deviation from constancy. As described above, it is possible to detect an overload of the switch and/or the load in the load circuit. It is possible to reliably counteract a defect in the load circuit by emitting the signal, for example an overload signal.

Depending on the design of the switch and the load in the load circuit, it may be the case that the control variable goes into saturation, if the output variable is kept constant, without the need for overload disconnection of the switch or load. In the case of such a state, the load current can no longer be reliably determined from the value of the control variable since the latter is in saturation. In order to nevertheless be able to reliably determine the load current in this state, the evaluation unit is intended to determine the load current from both switch variables in another advantageous refinement of the invention. If the control variable is in saturation, the output variable will not be able to be kept constant, with the result that its value, in conjunction with the value of the control variable, is an indicator of the load current. This makes it possible to reliably determine the load current even in the saturation region of the switch.

If the load current in the load circuit is very low, it may be the case—depending on the characteristic curve of the switch—that the gradient of the control variable as a function of the output variable is very flat. In the case of such a set-up, the control variable must be evaluated with a very high resolution in order to be able to determine the load current with a high level of accuracy. In order to be able to manage with a relatively low resolution in this case, it is advantageous if the operating point or operating range on the characteristic curve is set, for the instantaneous low current, in such a manner that the characteristic curve is steeper at this operating point or in this operating range. For this purpose, the setting means is advantageously intended to set the operating range on the characteristic curve as a function of the load current. This may be effected in a particularly simple manner if the output variable to be kept constant is set as a function of the load current, for example by setting a reference variable in such a manner that an advantageous operating point or operating range is achieved with the output variable to be kept constant.

If, during operation of the load circuit, the load current falls to a flat region of the characteristic curve, it is advantageous to move the operating point—for an instantaneous or constant load current—to a steeper region of the characteristic curve immediately or quickly. For this purpose, the setting means is advantageously intended to lower the value of the switch variable, which is kept constant, in particular the output variable, when the load current undershoots a predetermined value.

In the case of a high load current, in particular, it is advantageous if the switch has a low resistance. In order to keep the resistance of the switch low, the latter advantageously has switching elements which are connected in parallel, for example two switching elements which are connected in parallel, the corresponding switch variables of both switching elements being treated the same. In order to determine the load current, the corresponding switch variable is expediently kept constant in both elements.

The second switching element can be advantageously connected to the first switching element which is already operating, for example in the case of an instantaneous high load current.

In addition, the invention is aimed at a method for measuring a load current in a load circuit having a switch which is intended to switch the load current and has a control variable as a first switch variable and an output variable, which is dependent on the control variable, as a second switch variable, a setting means keeping one of the switch variables constant at a predetermined value, and an evaluation unit determining the load current from the other switch variable. Advantageous embodiments of the method can be achieved with the features described above.

Further advantages emerge from the following description of the drawing. Exemplary embodiments of the invention are illustrated in the drawing. The drawing and the description contain numerous features in combination which will also be expediently considered individually and combined to form expedient further combinations by a person skilled in the art.

Other features which are considered as characteristic for the invention are set forth in the appended claims.

Although the invention is illustrated and described herein as embodied in apparatus for measuring a load current, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 shows a simplified circuit diagram of an apparatus for measuring a load current in a load circuit having a switch;

FIG. 2 shows graphs of the load current, the control variable and the output variable of the switch and activity state signals, each with respect to time;

FIG. 3 shows graphs as in FIG. 2 but with further activity states;

FIG. 4 shows a block diagram of the apparatus;

FIG. 5 is a block diagram of an exemplary mockup of the novel circuit (active diode) in combination with a discrete output; and

FIG. 6 is a schematic block diagram of an exemplary discrete output active diode.

### DETAILED DESCRIPTION OF THE INVENTION

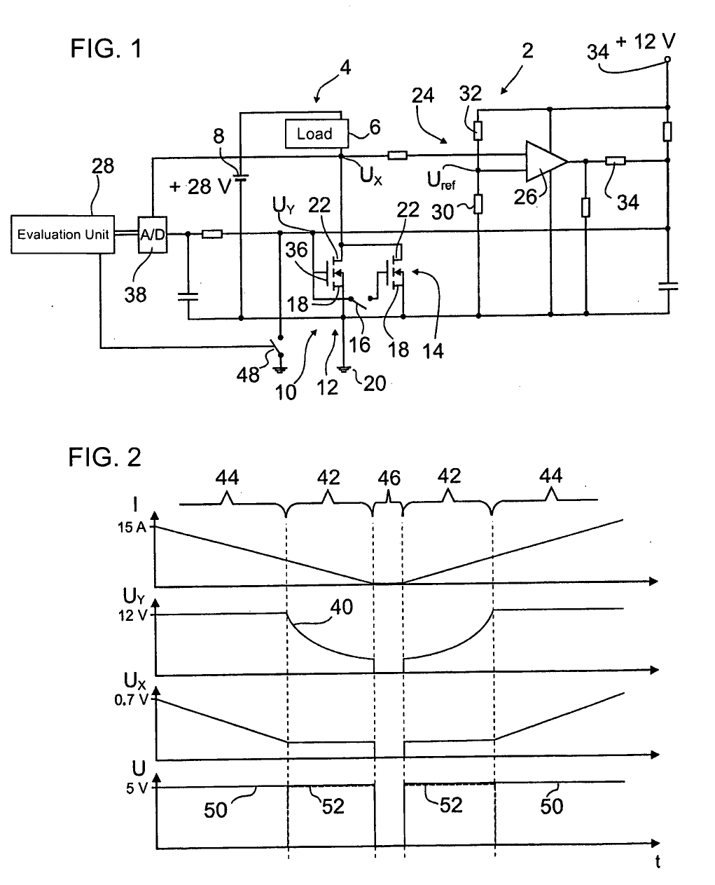

Referring now to the figures of the drawing in detail and first, particularly, to FIG. 1 thereof, there is shown a simplified circuit diagram of an apparatus 2 for measuring a load current I in a load circuit 4. The apparatus 2 comprises the load circuit 4 in which a load 6, for example a motor, is arranged and which has a voltage supply 8. In order to switch the load current I on and off, the load circuit 4 is provided with a switch 10 having two switching elements 12, 14 each in the form of a MOSFET. The switching element 14 can be connected in parallel with the switching element 12 by means of a switch 16, the source 18 of said switching element 14 being connected to a grounding arrangement 20 and the drain 22 of said element being connected to the load 6.

In order to measure the load current I, the apparatus 2 also comprises a setting means 24 in the form of a control loop for keeping a switch variable of the switch 10 constant, the output variable of the switch 10 in this case in the form of a switch voltage U_{X} across the switch 10, that is to say the voltage drop between the drain 22 and the source 18. The core of the setting means 24 is an operational amplifier 26 (a comparator would also be possible) whose inputs are connected, on the one hand, to the switch 10, to the drain 22 of the switch 10 in this exemplary embodiment, and, on the other hand, to a reference voltage U_{ref}. The reference voltage U_{ref} can be set by an evaluation unit 28, also referred to as an evaluation means, with the result that there is a controllable reference source. The controllability can be achieved, for example, by means of a D/A converter whose digital input is connected to the evaluation unit 28 and whose analog output forms the reference source. A voltage divider, as illustrated in FIG. 1 for example, is likewise possible. In this case, the evaluation unit 28 is connected to two variable resistors 30, 32, these connections not being illustrated in FIG. 1 for the sake of clarity. The resistors 30, 32 are arranged between a control voltage supply 34 and the grounding arrangement 20, with the result that the potential of the reference voltage U_{ref} can be selected between the potential of the control voltage supply 34 and the grounding arrangement 20 by the evaluation unit 28.

The control output provides the control variable of the switch 10. For this purpose, in this exemplary embodiment, the output of the operational amplifier 26 is connected to the gate 36 of the switch 10 (via a further resistor) and provides the gate voltage U_{Y}. In order to determine the load current I from the control variable, the control output is connected to the evaluation unit 28 via an A/D converter 38. A low-pass filter having a resistor and a capacitor upstream of the A/D converter 38 is used to suppress interference in the control output, in particular in order to filter out the signal fluctuations of a comparator when the latter is used.

In addition, the output variable of the switch 10 in the form of the switch voltage U_{X} is in turn passed to the evaluation unit 28 via the A/D converter 38 in order to be able to determine the load current I from the gate voltage U_{Y} and the switch voltage U_{X}. In order to drive the switch 16, the evaluation unit 28 is also connected to the latter.

FIG. 2 shows graphs of the load current I, the control variable in the form of the gate voltage U_{Y}, the output variable in the form of the switch voltage U_{X}, and activity state signals 50, 52. The graphs are plotted against time t in order to illustrate the variables.

In the uppermost graph, the load current through the load 6 and the switch 10 is plotted against time t. In order to illustrate all activity states of the switch 10, the load current I—contrary to conventional reality—is plotted such that it changes in a linear manner from a high value, 15 A in this example, to zero and back to a high value. It goes without saying that the load current I can also have any other profile during operation.

In the second graph, the gate voltage U_{Y} is plotted against the same temporal profile, with the result that the relationship between the load current I and the gate voltage U_{Y} becomes visible. This relationship results from the characteristic curve 40 of the switch 10 and from the fact that the control loop attempts to keep the switch voltage U_{X} constant at any time and for any load current I, which is then present, and sets the gate voltage U_{Y} in a corresponding manner. Three activity states 42, 44, 46 of the switch 10 can be discerned from the gate voltage U_{Y}. In a first activity state 42 or a first control range of the load current I, the gate voltage U_{Y} is in an operating range of between approximately 3 V and 12 V. The load current I has values of between 0 A and approximately 5 A in this operating range.

If the load current I rises above this control range, that is to say above approximately 5 A, the switch 10 is in the activity state 44, an overload range in which, although the load 6 and the switch 10 can be operated if appropriate, the gate voltage U_{Y} cannot be changed in such a manner that the switch voltage U_{X}, which is illustrated in the third graph, is kept constant. The switch voltage U_{X} rises in a linear manner with the load current I. In a third activity state 46, a switch 48 (cf. FIG. 1) is open and the gate voltage U_{Y} is at ground potential or zero potential and a load current A does not flow: the switch 10 is open or in the “off position.” In the third activity state 46, the status of the switch 10 is thus “off,” whereas the status of the switch 10 is “on” in the activity states 42 and 44.

The fourth graph illustrates activity state signals 50, 52 which are generated by the evaluation unit 28, for example. The activity state signal 50 is the signal relating to the status of the switch 10 and indicates whether the switch 10 is “on” or “off”. The activity state signal 52 indicates whether the switch 10 is in the control range or in the overload range in which the switch 10 is still “on”.

During operation of the apparatus 2, the load circuit 4 may be put into operation first of all by closing the switch 10, that is to say switching it to its “on position”. This is carried out by the evaluation unit 28, another control means which closes the switch 48 and sets a reference voltage U_{ref} by driving the resistors 30, 32 in an appropriate manner also being possible. As a result, the load current in the load circuit 4 is released and is set in a manner corresponding to the resistance of the load 6 or of all components in the load circuit 4. In this case, during operation, the switch 10 has a resistance which is considerably lower than that of the load 6, for example only at most 1/100, in particular only at most 1/1000, of the resistance of the load 6 in the control range.

The control loop now keeps the switch voltage U_{X} constant at the potential of the reference voltage U_{ref}, a gate voltage U_{Y} being set according to the characteristic curve 40 illustrated in the second graph. This gate voltage U_{Y} is detected by the evaluation unit 28 and is used by the latter to determine the load current I from the known characteristic curve 40 for a predefined switch voltage U_{X}. For this purpose, an assignment of the switch variable, the gate voltage U_{Y} in this case, to the load current A, in particular as a function of the other switch variable, the switch voltage U_{X} in this case, is stored in the evaluation unit 28.

If the load current I, for example at the request of the load 6, rises to the overload range, the setting means 24 cannot keep the switch voltage U_{X} constant at the predefined value. The switch voltage U_{X} will rise above the value counter to control. In order to detect this state, the evaluation unit 28 monitors the switch voltage and outputs a signal, for example a change in the activity state signal 52 from “on” to “off”, in the case of a predetermined deviation of the switch voltage U_{X} from the predefined value.

In addition, evaluation of the gate voltage U_{Y} does not suffice to determine the load current in the overload range. Rather, the gate voltage U_{Y} is constant for this status 44 of the switch 10. However, the load current I is clearly related to the two switch variables, that is to say the gate voltage U_{Y} and the switch voltage U_{X}, with the result that the evaluation unit 28 determines the load current from both switch variables in the overload range.

In order to keep the resistance of the switch 10 low, the second switching element 14 can be activated by the evaluation unit 28 by closing the switch 16. This option is available not only in the activity state 44 but also during normal operation in order to keep the power loss in the switch 10 low.

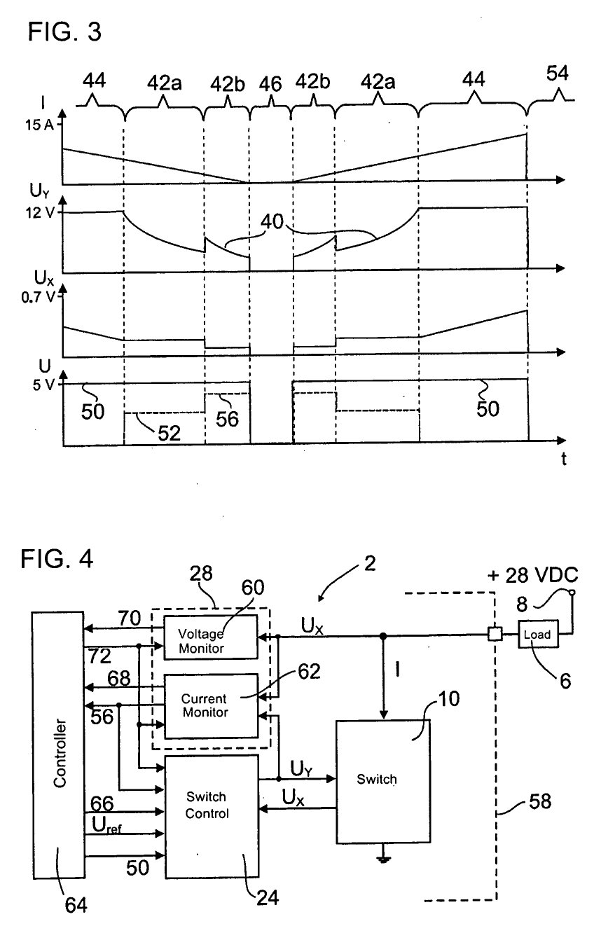

FIG. 3 shows graphs as in FIG. 2 but with changed control by the evaluation unit 28, as a result of which the activity state 42 is subdivided into two activity states 42a and 42b and a new activity state 54 is created. The activity state 42b is used to measure the load current I in the range of low currents. If the load current I in the load circuit 4 falls below a value stored in the evaluation unit 28, for example below 200 mA, an activity state signal 56 is output by the evaluation unit 28 and the reference voltage U_{ref}, which, in order to keep the switch voltage U_{X} constant, is likewise kept constant by the evaluation unit 28, is lowered, for example from 100 mV to 50 mV. As a result of the fact that the reference voltage U_{ref} is lowered, the gate voltage U_{Y} is controlled by the control loop in such a manner that the switch voltage U_{X} is set to the value of the reference voltage U_{ref}, that is to say is likewise lowered. As a result, the operating point of the gate voltage U_{Y} is in a region of the characteristic curve 40 of relatively great steepness, with the result that the resolution for measuring the load current I becomes greater. The characteristic curve 40 is thus shifted in such a manner that the operating point on the characteristic curve 40—an operating range on the characteristic curve 40 in the case of a fluctuating load current I—becomes steeper. As a result of the steeper gradient of the characteristic curve 40, the load current I can be determined in a more accurate manner without additional outlay on apparatus.

However, the load current range also becomes smaller as a result, and so only relatively low load currents I can be measured using the gate voltage U_{Y}. It is therefore advantageous if the switch voltage U_{X} is raised once more by the evaluation unit 28, when the load current I rises above the predetermined value, by raising the reference voltage U_{ref}. As a result, the switch 10 assumes the activity state 42a again. In order to avoid flickering of the activity states 42a, 42b, it is possible to provide hysteresis which switches an activity state 42a, 42b, which was changed over in the case of a value W, back again only in the case of the value of, for example, W+20 mV or W −20 mV, depending on the changeover direction.

If the load current I through the load 4 continues to rise, with the result that the overload range is reached, although this is registered by the evaluation unit 28 by virtue of a change from the activity state 42a to the activity state 44, the switch 10 is not opened in order to interrupt the load current I. This is effected only when the load current I rises above a further predetermined value, for example 12 A, and thus reaches the activity state 54. When the activity state 54 is reached, the activity state signal 50 is changed by the evaluation unit 28, for example is set to zero, and the switch 48 is thus opened and the gate voltage U_{Y} is thus set to zero, with the result that the switch 10 blocks the load current I.

FIG. 4 illustrates the principle of the invention in a simplified block diagram. The apparatus 2 is arranged in a housing 58, without the load 6 and the voltage supply 8 in this exemplary embodiment, which are outside the housing 58. The load current I flows through the switch 10, as a result of which the switch voltage U_{X} can be tapped off by a voltage monitor 60 of the evaluation unit 28. The control variable, the gate voltage U_{Y} in this case, is monitored by a current monitor 62 of the evaluation unit 28, the switch voltage U_{X} also being input to the current monitor 62 in order to determine the load current I in the overload range. The setting means 24, the control loop in this case, receives the switch voltage U_{X} as a control input and outputs the gate voltage U_{Y}.

In this exemplary embodiment, the control loop and the switch 10 are not controlled by the evaluation unit 28 but rather by a control means 64 which outputs the reference voltage U_{ref}, a reset of the switch 48 with the activity state signal 50, and a command signal 66 for controlling the setting means 24. It is also possible to integrate the evaluation unit 28 in the control means 64 or vice versa. The activity state signals 52, 56 relating to the overload range and the low-load range are output by the current monitor 62; the signal 68 relating to the instantaneous load current I is likewise output by the current monitor. The signal 70 relating to the instantaneous switch voltage U_{X} is transmitted from the voltage monitor 60 to the control means 64 which configures the voltage monitor 60, the current monitor 62 and the setting means 24 in a signal 72.

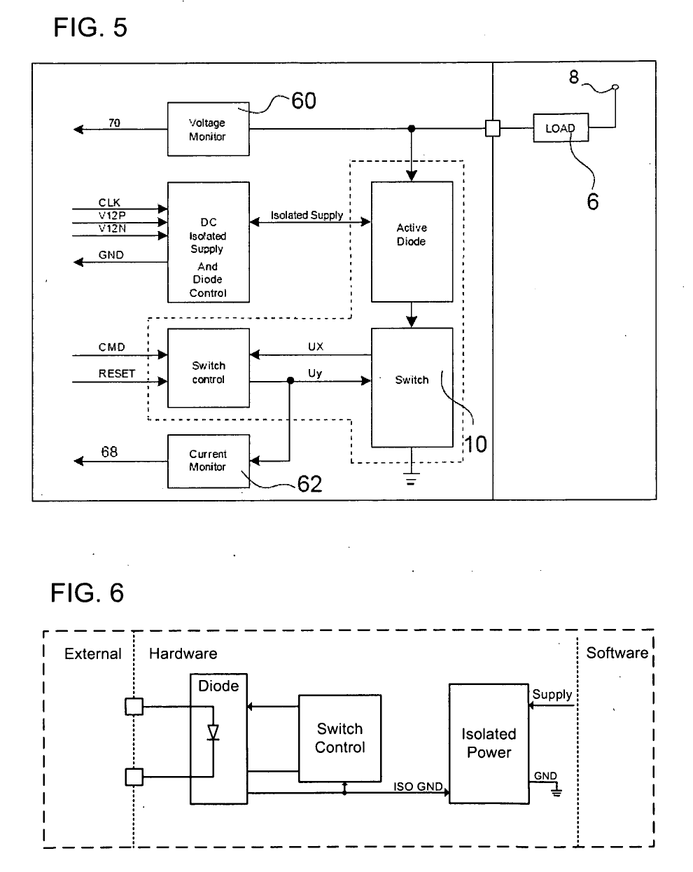

Referring now to FIGS. 5 and 6, there is illustrated a mockup implementation of the novel circuit for laboratory testing with realistic signal connections. The active diode represents an interface to replace a decoupling diode for discrete output interfaces. The active diode is set to have a minimum forward voltage drop. If a reverse voltage is applied to the interface, the diode switches automatically in a high impedance state.

The interface function of FIG. 5 characterizes an active diode with a minimum forward voltage drop. The function is to reduce the forward voltage and to change to high impedance state if reverse voltage is applied to the diode. The active diode may be used in combination with standard discrete output interfaces, such as, for example, DSO GND open or DSO 28V open for decoupling purposes.

The active diode is especially designed for high current discrete interfaces. According to the invention, no control signal from the SW need be used for the active diode. FIG. 5 shows the diode in combination with a DSO GND OPN (discrete output ground open) interface type. If isolated power for the active diode fails, the failure can be detected by monitoring the voltage drop of the interface.

The mockup of FIGS. 5 and 6 covers the discrete output switch function which is controlled with a manual switch to turn on or off the FET. With reference to FIG. 6, the active diode may be implemented with an FET which is controlled by a voltage monitor. The active diode electronic is supplied by a separate isolated supply voltage. The active diode circuit of FIG. 6 includes the isolated power supply, the switch control and the diode. The active diode for the mockup is further indicated within the dashed box inside FIG. 5, wherein the two mockups are combined for laboratory testing.

1. A device for measuring a load current in a load circuit, comprising:
a switch for switching the load current, said switch having a control variable forming a first switch variable and an output variable forming a second switch variable, the output variable being dependent on the control variable;
setting means connected to said switch and configured to keep one of the switch variables constant at a predetermined value; and
an evaluation unit configured to determine the load current from the other switch variable.

2. The device according to claim 1, wherein said switch is a switch with a characteristic curve.

3. The device according to claim 1, wherein the output variable is a switch voltage across the switch, and said setting means is configured to keep the switch voltage across the switch constant.

4. The device according to claim 1, wherein said setting means comprises a control loop for keeping the switch variable constant.

5. The device according to claim 1, wherein said evaluation unit is configured to determine an activity state of said switch from one of the switch variables.

6. The device according to claim 5, wherein the activity state is a status of the switch.

7. The device according to claim 1, wherein said evaluation unit is configured to monitor the switch variable that is kept constant and to emit a signal in the case the monitored switch variable deviates from the constant value by a predetermined deviation amount.

8. The device according to claim 1, wherein said evaluation unit is configured to determine the load current from the first and second switch variables.

9. The device according to claim 1, wherein said switch is a switch with a characteristic curve, and said setting means is configured to set the operating range on the characteristic curve as a function of the load current.

10. The device according to claim 9, wherein said setting means is configured to lower a value of the switch variable, which is kept constant, when the load current undershoots a predetermined value.

11. The device according to claim 1, wherein said switch has switching elements connected in parallel, and said evaluation unit is configured to treat the corresponding switch variables of said switching elements equally.
